(19) United States
(12) Patent Application Publication
(10) Pub. No.: US 2004/0262723 A1
(43) Pub. Date: Dec. 30, 2004

(54) Semiconductor device

(75) Inventors: Zhikang Qin, Tokyo (JP); Yasuki Takata, Tokyo (JP); Hiroshi Horibe, Tokyo (JP); Fumiaki Aga, Tokyo (JP); Noriaki Higuchi, Tokyo (JP); Yasuhito Suzuki, Tokyo (JP)

Correspondence Address: McDermott, Will & Emery, 600 13th Street, N.W., Washington, DC, 20005-3096, US

(73) Assignee: Renesas Technology Corp.

(21) Appl. No.: 10/874,354

(22) Filed: Jun. 24, 2004

(30) Foreign Application Priority Data
Jun. 24, 2003 (JP) 2003-180062

(51) Int. Cl. H01L 21/48; H01L 23/52

(52) U.S. Cl. 257/676; 257/692; 438/123; 257/784; 438/617

(57) ABSTRACT

At least one of a corner portion of the semiconductor chip, a corner portion of the sealing member, and a portion in which two neighboring gold wires are spaced at a larger distance than any other two neighboring gold wires adjacent to the two neighboring gold wires is configured such that one electrode and another electrode adjacent to it are arranged in such a way that the space between one gold wire connected to one electrode and another gold wire connected to another electrode and adjacent to one gold wire is substantially equal to the diameter of these gold wires when one gold wire has been displaced toward another gold wire due to a flow of a resin at a time of sealing with the resin.

### BACKGROUND OF THE INVENTION

1. Field of the Invention

The present invention relates to a semiconductor device, and more particularly to a semiconductor device in which the semiconductor chip, the mounting portion, one end of each external electrode terminal, and the connection lines are sealed in a resin.

2. Background Art

In recent years, there has been an increasing demand for smaller and thinner semiconductor packages with higher integration density. As such, there has been a tendency to reduce the size of the pads provided on the surface of each semiconductor chip which are connected to the inner leads through slack gold wires, as well as reducing the distance between each pad. Furthermore, the diameter of each gold wire has been reduced while its length has been increased. For example, even though gold wires having a diameter of approximately 28 μm have been conventionally used, it is considered that the diameter of gold wires in the future must be set to 25 μm or less.

Incidentally, each semiconductor device is configured such that the semiconductor chip, the die pad, on which the semiconductor chip is mounted, the gold wires, and the inner leads are sealed in a resin. Specifically, the sealing step is carried out as follows. After fabricating the components of the semiconductor device, they are put into a predetermined mold and a resin is injected therein through the fill port provided at a corner of the mold.

However, there is a problem with semiconductor packages in which the gold wire diameter is small and the distances between the gold wires are reduced due to reduced pad pitch, in that the gold wires stream when the resin is injected into the mold at the sealing step.

FIG. 6 is a plan view of a conventional semiconductor device. It should be noted that the figure only shows a semiconductor chip 120 and gold wires 121 in the semiconductor device and omits the other components. The resin injected from a fill port 122 flows in the direction indicated by each arrow. At that time, every gold wire streams by the action of the resin flow. Especially, the gold wires in the corners of the resin (mold) and the semiconductor chip stream a large distance, which may cause neighboring gold wires to come into contact with one another, resulting in a short circuit.

This problem may arise with not only QFP (Quad Flat Package) type packages as shown in FIG. 6 but also SOP (Small Outline Package) type packages as shown in FIG. 7.

In FIG. 7, outer leads 124 protrude from two sides of a package 123. Inside the package 123, the inner leads (not shown) extending from the outer leads 124 are connected to gold wires (not shown). The resin injected from a fill port 125 flows in the direction indicated by the arrow, causing every gold wire to stream. As in the example shown in FIG. 6, gold wires stream a large distance particularly in the corner portions and in the portions in which two neighboring gold wires are spaced at a larger distance than any other two neighboring gold wires adjacent to them, thereby causing neighboring wires in these portions come into contact with one another, resulting in a short circuit.

### SUMMARY OF THE INVENTION

The present invention has been devised in view of the above problem. It is, therefore, an object of the present invention to provide a semiconductor device configured such that no short circuit occurs between gold wires in the semiconductor package sealing process.

According to one aspect of the present invention, a semiconductor device comprises a semiconductor chip including a plurality of electrodes, a mounting portion on which the semiconductor chip is mounted, a plurality of external electrode terminals, one end of each external electrode terminal being disposed so as to face the semiconductor chip, the other end of each external electrode terminal being connected to an external component or device, a plurality of connection wires each for connecting between one of the plurality of electrodes and one end of one of the plurality of external electrode terminals, and a sealing member for resin-sealing the semiconductor chip, the mounting portion, the one end of the each external electrode terminal, and the plurality of connection wires, the sealing member having a rectangular shape. At least one of a corner portion of the semiconductor chip, a corner portion of the sealing member, and a portion in which two neighboring connection wires are spaced at a larger distance than any other two neighboring connection wires adjacent to the two neighboring connection wires is configured such that an electrode and another electrode adjacent to it are arranged such that the space between a connection wire connected to the electrode and another connection wire connected to the another electrode is substantially equal to the diameter of the connection wires when the connection wire connected to the electrode has been displaced toward the another connection wire connected to the another electrode due to a flow of a resin at a time of the resin-sealing, the connection wire and the another connection wire being adjacent to each other.

Other and further objects, features and advantages of the invention will appear more fully from the following description.

### BRIEF DESCRIPTION OF THE DRAWINGS

FIG. 1A is an enlarged plan view of a portion of a semiconductor device according to the present invention.

FIG. 1B is an enlarged plan view of a pair of neighboring gold wires of a semiconductor device in FIG. 1A.

FIG. 2 is an enlarged plan view of a portion of a semiconductor device according to a first embodiment.

FIG. 3 is an enlarged plan view of a portion of a semiconductor device according to a first embodiment.

FIG. 4 is an enlarged plan view of a portion of a semiconductor device according to a second embodiment.

FIG. 5 is an enlarged plan view of a portion of a semiconductor device according to a third embodiment

FIG. 6 is a plan view of a conventional semiconductor device.

FIG. 7 is a plan view of a conventional semiconductor device.

### DETAILED DESCRIPTION OF THE PREFERRED EMBODIMENTS

According to the present invention, a semiconductor device is configured such that the electrodes are spaced at larger intervals in the portions in which gold wires may become shorted due to their streaming movement than in the portions in which no short circuit can possibly occur. This arrangement can prevent the gold wires from coming into contact with one another and thereby prevent occurrence of a short circuit even when they stream a large distance.

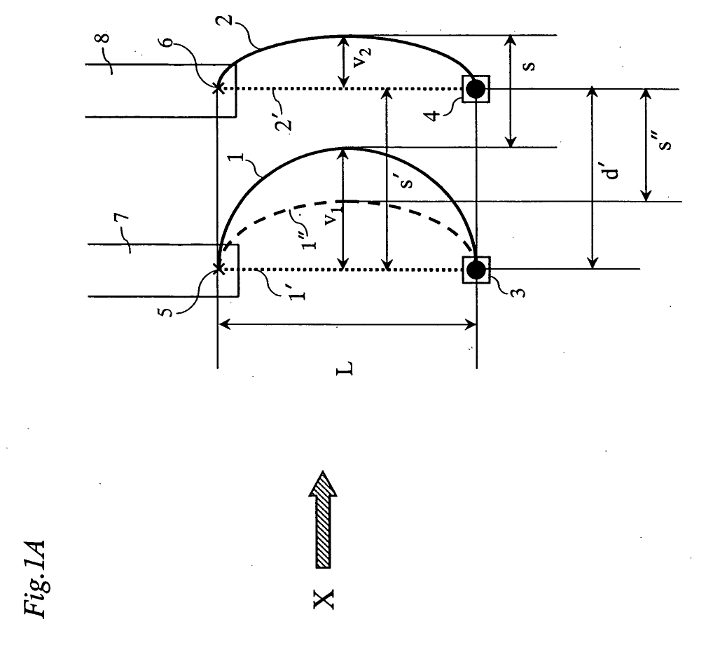

A description will be given of how to lay out each electrode according to the present invention with reference to FIG. 1A and 1B. FIG. 1A schematically shows how two neighboring gold wires A and B stream due to a resin flow. In the figure, arrow X indicates the direction of the resin flow; the two solid lines labeled with reference numerals 1 and 2 respectively indicate the positions of the two gold wires A and B when they have streamed; and the two dotted lines labeled with reference numerals 1′ and 2′ respectively indicate the positions of the gold wires A and B before they stream. One end of the gold wire A is connected to an electrode 3 while the other end is connected to an inner lead 7 at a stitch point 5. On the other hand, one end of the gold wire B is connected to an electrode 4 while the other end is connected to an inner lead 8 at a stitch point 6.

Referring to FIG. 1A, the gold wires A and B are assumed to run parallel to each other before they stream as indicated by the dotted lines 1′ and 2′. Further, if L denotes the length of the gold wires A and B, and v₁ and v₂ respectively denote the amounts of displacement of the gold wires A and B due to their streaming movement, the gold wire streaming factors x₁ and x₂ of the gold wires A and B, respectively, are expressed by Equation 1 below. It should be noted that the amount of displacement of a gold wire due to its streaming movement depends on its rigidity; specifically, the amount of displacement changes with changing composition or diameter of the gold wire.

x₁=(v₁/L)×100(%)

x₂=(v₂/L)×100(%) [Equation 1]

Referring to FIG. 1A, when the gold wire streaming factors x₁ and x₂ are such that x₁=x₂ or x₁<x₂, no short circuit occurs since the gold wires A and B cannot possibly come into contact with each other. When x₁>x₂, on the other hand, a short circuit can occur between the gold wires A and B. However, if the gold wires A and B are spaced more than a certain distance from each other, the occurrence of a short circuit can be prevented. It should be noted that the space between the gold wires A and B (at the positions 1 and 2 respectively) when they have streamed is preferably set substantially equal to the diameter of these gold wires, considering the measurement accuracy of the equipment for measuring such a distance and the time it takes to complete the measurement.

As shown in FIG. 1A and 1B, if s denotes the space between the gold wires A and B when they have streamed (as indicated by the solid lines 1 and 2), and s′ denotes the space between them before they stream (as indicated by the dotted lines 1′ and 2′), then s=s′−v₁+v₂. Therefore, from Equation 1, the distance s is expressed by Equation 2 below.

s=s′−(L/100)(x₁−x₂) [Equation 2]

The value of the term “x₁−x₂” in Equation 2 can be experimentally obtained. Therefore, for example, if it is assumed that the space s is equal to the diameter of the gold wires, the space s′ can be obtained by substituting the value of the gold wire length L and the value of the term “x₁−x₂” into Equation 2. It should be noted that the space s′ corresponds to the distance between the electrodes 3 and 4 to which the gold wires A and B are connected, respectively. Therefore, the distance between the electrodes 3 and 4 may be set equal to the space s′ to prevent the gold wires A and B from coming into contact with each other. This arrangement can also be applied to other electrodes. That is, the electrodes to which each two neighboring gold wires are connected may be spaced an appropriate distance from each other to provide a layout of electrodes in which no short circuit can possibly occur.

Incidentally, the gold wire streaming factor of each gold wire varies depending on the package. Therefore, the present inventor has obtained the difference between the gold wire streaming factors of each two neighboring gold wires in each package, and found that if the difference between the streaming factors of each two neighboring gold wires is equal between two packages, the same layout of electrodes may be applied to both of them. This means that an appropriate layout of electrodes for each package can be easily determined by assuming that only the gold wire A streams in resin. Specifically, referring to FIG. 1A, if it is assumed that only the gold wire A is displaced, as indicated by dashed line 1″, and the gold wire B is not displaced, then the (equivalent) gold wire streaming factor x₃ of the gold wire A is equal to x₁−x₂. In this case, the space s″ between the gold wires A and B (at the positions 1″ and 2′ respectively) when only the gold wire A is assumed to have streamed is expressed by Equation 3 below.

s″=s′−(L×x₃/100) [Equation 3]

The value of x₃ in Equation 3 can be experimentally obtained. Therefore, if it is assumed that the space s″ is equal to the diameter of the gold wires, the space s′ can be obtained by substituting the value of x₃ into Equation 3. The value for the space s′ thus obtained can be applied to any package whose gold wire streaming factor x₃ (that is, the difference between the actual streaming factors of the two gold wires A and B) is set to the above value for x₃.

Preferred embodiments of the present invention will be described below in detail with reference to the accompanying drawings. It should be noted that the present invention can be applied to general resins used to seal semiconductor chips, etc., for example, resins having a viscosity of 70 ps-460 ps.

First Embodiment

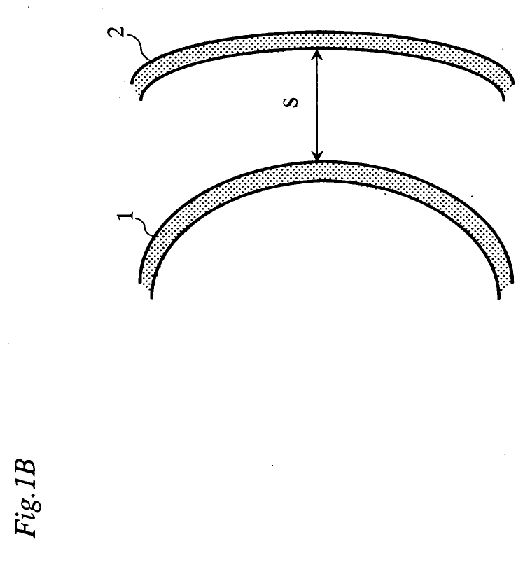

FIG. 2 is an enlarged plan view of a portion of a semiconductor device according to a first embodiment of the present invention. The semiconductor chip is mounted on a mounting portion(not shown), and the chip, the mounting portion, one end of each external electrode terminal (described later), and the gold wires (described later) are sealed with a sealing member. Referring to FIG. 2, reference numeral 11 denotes the circumference of the semiconductor chip and reference numeral 12 denotes the circumference of the sealing member. Specifically, FIG. 2 shows corner portions of the semiconductor chip and the sealing member, which each have a rectangular shape. In the example of FIG. 2, a diagonal line A of the semiconductor chip coincides with a corresponding diagonal line B of the sealing member.

When the semiconductor device is sealed, the resin injected from the fill port (not shown) first flows in the direction indicated by arrow X to reach the corner portion and then changes its direction and flows in the direction indicated by arrow Y. This resin flow causes every gold wire to stream. In the corner portion, the resin stays for a while and then begins to flow again. Because of this phenomenon, the gold wires in the corner portion are likely to stream a large distance, leading to a short circuit. More specifically, the closer a gold wire to the corner, the larger the distance it streams.

The present inventor has intensively studied this problem focusing on the 6 gold wires on each side of the corner (that is, each side of the diagonal line A (or B) indicated by the dashed line in FIG. 2) and found that the distance between the electrodes to which each two neighboring gold wires are connected may be appropriately changed to prevent occurrence of a short circuit between gold wires, as described below.

Referring to FIG. 2, if it is assumed that the gold wire streaming factors of gold wires 15 and 16 are a %, those of gold wires 14 and 17 are b %, and those of gold wires 13 and 18 are c %, then the following relation holds: a>b>c. It should be noted that each dotted line other than that indicating the diagonal lines A and B indicates the position of a gold wire before it streams. It should be further noted that in addition to the gold wires 13, 14, 15, 16, 17, and 18, other gold wires also actually stream, but their gold wire streaming factors are less than c %. (For simplicity, the figure assumes that these other gold wires do not stream.)

Each gold wire is connected between an electrode and one end of an inner lead of the semiconductor chip. For example, the gold wire 13 is connected between the electrode 19 and the inner lead 26. Each inner lead is a portion of an external electrode terminal and is disposed within the sealing member such that it faces the semiconductor chip. Further, the other end of each inner lead extends from an outer lead (not shown) connected to an external component or device; that is, each external electrode terminal is divided into an inner lead and an outer lead.

Even though every gold wire streams due to a resin flow, as described above, the present embodiment allows focusing on only the gold wires 13, 14, 15, 16, 17, and 18. That is, the electrodes to which these gold wires are connected may be spaced at larger intervals than the other electrodes by a predetermined amount. Specifically, the electrodes to which each two neighboring gold wires are connected are spaced from each other such that the space between the two neighboring gold wires is substantially equal to their diameter when they have streamed.

First of all, the gold wire streaming factor of each gold wire is experimentally obtained. Assume, for example, that the obtained gold wire streaming factors of the gold wires 13 and 18 are 2.0%, those of the gold wires 14 and 17 are 2.5%, and those of the gold wires 15 and 16 are 3.0%. It should be noted that in the above case, each gold wire streaming factor corresponds to the gold wire streaming factor X₃ in the example of FIG. 1A. Then, each space s′ is obtained by substituting 23 μm (equal to the diameter of the gold wires) for the space s″ and 4.1 mm for the gold wire length L in Equation 9. Each space s′ is the space between neighboring two of the electrodes 19, 20, 21, 22, 23, 24, and 25. It should be noted that the pitch at which the inner leads connected to these gold wires are disposed is set to a conventional fixed value (250 μm).

FIG. 2 shows an arrangement of the electrodes made based on each value of s′ thus obtained. As shown in FIG. 2, the electrodes 22 and 23 are spaced at a distance of approximately 170 μm. Further, the distance between the electrodes 20 and 21 and that between the electrodes 23 and 24 are both set to approximately 130 μm, while the distance between the electrodes 19 and 20 and that between the electrodes 24 and 25 are both set to approximately 95 μm. It should be noted that other electrodes adjacent to these electrodes are spaced at intervals of approximately 80 μm, which is a conventional value used when all electrodes are equally spaced.

As shown in FIG. 2, of the above electrodes, the electrodes 22 and 23 are spaced at the largest distance. The electrode 22 is the electrode to which the gold wire 16 having the largest gold wire streaming factor is connected, while the electrode 23 is the electrode to which the gold wire 17 adjacent to the gold wire 16 is connected. (The gold wire 16 is displaced toward the gold wire 17.) On the other hand, the gold wire 15 also having the largest gold wire streaming factor is disposed adjacent to the corner and is displaced toward the corner due to its streaming movement. Therefore, the space between the gold wires 15 and 16 is designed to be larger than the distance between any other two neighboring gold wires adjacent to these gold wires. This means that no consideration need be given to the distance between the electrodes 21 and 22 to which the gold wires 15 and 16 are connected, respectively.

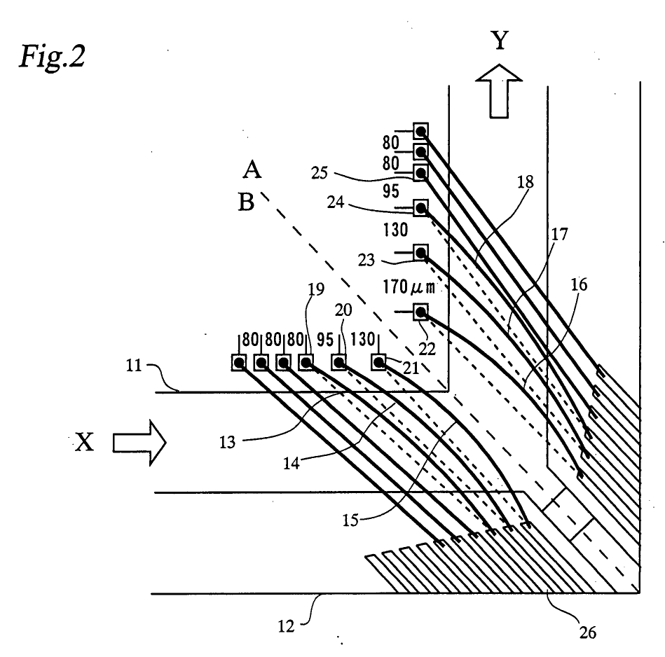

FIG. 3 shows an exemplary semiconductor device in which a diagonal line A of the semiconductor chip does not coincide with a corresponding diagonal line B of the sealing member. In such a case, the gold wires around each of the diagonal lines A and B must be taken into account, as follows.

The process for determining a layout of electrodes begins by selecting, for example, three gold wires 40, 41, and 42 connected to three electrodes 30, 31 and 32 on one side of the diagonal line A and further selecting three gold wires 43, 44, and 45 connected to three electrodes 33, 34, and 35 on the other side. In addition, the process selects three gold wires 44, 45, and 46 connected to three inner leads 50, 51, and 52 on one side of the diagonal line B and further selects three gold wires 47, 48, and 49 connected to three inner leads 53, 54, and 55 on the other side. Since the gold wires 44 and 45 have been selected twice, a total of 10 gold wires, namely the gold wires 40, 41, 42, 43, 44, 45, 46, 47, 48, and 49, have been selected. The distance between the electrodes to which each neighboring two of these selected gold wires are connected is determined in the same manner as in the example shown in FIG. 2, and then the electrodes are arranged based on the determined distances. It should be noted that electrodes other than the above selected electrodes may be spaced from one another in a conventional manner. The above arrangement can prevent gold wires from coming into contact with one another due to their streaming movement, thereby preventing occurrence of a short circuit. It should be noted that the pitch at which the inner leads connected to the above selected gold wires are disposed may be set to a conventional value.

In the example shown in FIG. 3, a total of 10 gold wires were selected. However, the number of gold wires to be checked varies depending on the positional relationship between each corner portion of the semiconductor chip and a corresponding corner portion of the sealing member. The example shown in FIG. 2 requires the smallest number of gold wires to be checked, namely 6 gold wires. If none of the 3 gold wires on each side of a diagonal line of the semiconductor chip coincides with any of the 3 gold wires on each side of a corresponding diagonal line of the sealing member, the largest number of gold wires must be checked, that is, a total of 12 gold wires.

In this case, a determination is made of the distance between the electrode to which each selected gold wire is connected and the neighboring electrode thereof in the direction in which the gold wire is displaced when the semiconductor device is sealed with a resin. Then, the electrodes are arranged based on the determined distances. The distance between each two neighboring electrodes is calculated in accordance with Equation 4 below, which is obtained as a result of transforming Equation 2.

d=d+(L/100)(x₁−x₂) [Equation 4]

In Equation 4, d′ is the distance between two neighboring electrodes; d, the diameter of two neighboring gold wires 1 and 2 (connected to the electrodes); L, the length of the gold wires 1 and 2; x₁, the gold wire streaming factor of the gold wire 1; and x₂, the gold wire streaming factor of the gold wire 2. In the example shown in FIG. 3, for example, the gold wire streaming factors of the gold wires 40 and 41 are substituted for x₁ and x₂ in Equation 10.

According to the present embodiment, a semiconductor device is configured such that the pads in the corner portions are spaced at larger intervals than other pads adjacent to them by a predetermined amount, making it possible to prevent gold wires from coming into contact with one another and thereby prevent occurrence of a short circuit even when they are displaced due to their streaming movement. Further, the space between each two neighboring gold wires when they have streamed is set approximately equal to their diameter, making it possible to set the spaces between gold wires to within the measurement limit of inspection equipment as well as measuring these distances in a short time.

Still further, according to the present embodiment, it is only necessary to perform the steps of: selecting six gold wires respectively connected to six electrodes, three on each side of a diagonal line of the semiconductor chip; selecting six gold wires respectively connected to six inner leads, three on each side of a corresponding diagonal line of the sealing member; and changing the distances between the electrodes to which these selected gold wires are connected. Furthermore, according to the present embodiment, the electrodes are arranged such that the space between each two neighboring gold wires is substantially equal to the diameter of these gold wires when they have streamed. That is, the distances between neighboring electrodes determined according to the present embodiment are larger than those determined in a conventional manner only by a minimum amount required to prevent gold wires from coming into contact with one another, making it possible to prevent occurrence of a short circuit between gold wires due to their streaming movement even in a semiconductor package of substantially conventional size.

Still further, the present embodiment determines an appropriate layout of electrodes based on the difference between the gold wire streaming factors of each two neighboring gold wires, making it possible to determine the distances between electrodes in different types of packages in the same manner.

Second Embodiment

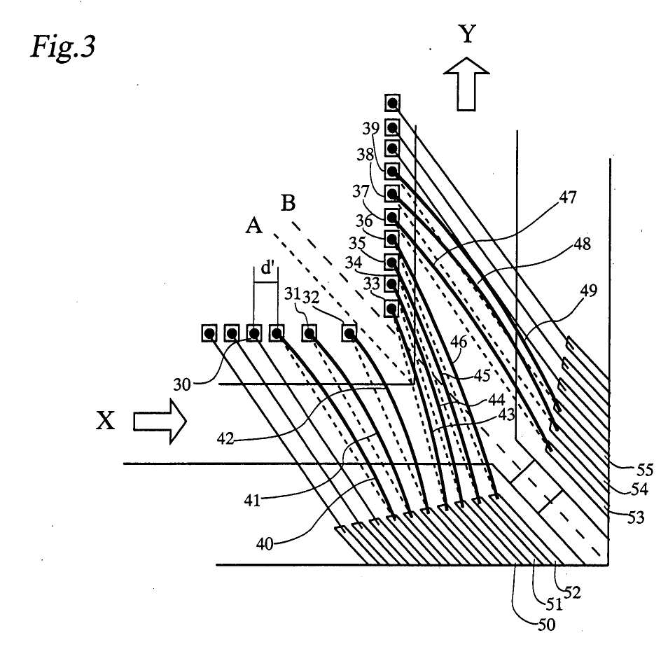

FIG. 4 is an enlarged plan view of a portion of a semiconductor device according to a second embodiment of the present invention. Referring to the figure, reference numeral 60 denotes the circumference of the semiconductor chip. The semiconductor chip is mounted on a mounting portion (not shown), and the chip, the mounting portion, one end of each external electrode terminal (described later), and the connection wires (described later) are sealed with a sealing member (not shown).

Referring to FIG. 4, a gold wire 61 is connected between an electrode 71 and one end of an inner lead 81. It should be noted that the inner lead 81 is a portion of an external electrode terminal and is disposed within the sealing member such that it faces the semiconductor chip 70. Further, the other end of the inner lead 81 extends from an outer lead (not shown) connected to an external component or device. The other gold wires 62 to 66 are also connected between their respective electrodes and their respective inner leads in the same manner.

Every semiconductor device has portions in which two neighboring electrodes (to which two neighboring gold wires are respectively connected) are spaced at a larger distance than any other two neighboring electrodes adjacent to these electrodes in order to suit design needs. If the distance between such neighboring electrodes is larger than a certain value, the flow of the resin injected to seal the semiconductor device changes at these portions, increasing the distance the gold wires stream.

In FIG. 4, the resin flowing in the direction indicated by arrow X causes every gold wire to stream. It should be noted that an electrode 73 to which a gold wire 63 is connected is spaced a distance of approximately 400 μm from an electrode 74 to which a gold wire 64 is connected. At such a portion, the flow of the resin changes, increasing the distance the gold wires stream, which makes a short circuit between gold wires likely to occur. To solve this problem, the present embodiment performs the steps of: selecting the electrodes 73 and 74, and further selecting electrodes 71 and 72 on the left side of the electrode 73 as well as electrodes 75 and 76 on the right side of the electrode 74 (that is, selecting a total of 6 electrodes); determining the distance between each selected electrode and the neighboring electrode thereof in the direction (the X direction) in which the gold wires are displaced when the semiconductor is sealed with a resin; and arranging the electrodes based on each determined distance.

According to the present embodiment, the amount of displacement of a gold wire due to its streaming movement (that is, the distance the gold wire streams) increases with decreasing distance from the portion in which two neighboring electrodes are spaced at a larger distance than any other two neighboring electrodes adjacent to these electrodes. Referring to FIG. 4, if it is assumed that the gold wire streaming factors of the gold wires 63 and 64 are a %, those of the gold wires 62 and 65 are b %, and those of the gold wires 61 and 66 are c %, then the following relation holds: a>b>c. It should be noted that each dotted line indicates the position of a gold wire before it streams. It should be further noted that in FIG. 4, in addition to the gold wires 61, 62, 63, 64, 65, and 66, other gold wires also actually stream, but their gold wire streaming factors are less than c %. (For simplicity, the figure assumes that these other gold wires do not stream.)

Even though every gold wire streams due to a resin flow, as described above, the present embodiment allows focusing on only the gold wires 61, 62, 63, 64, 65, and 66. That is, the electrodes to which each neighboring two of these gold wires are connected may be spaced at a larger distance than any other two neighboring electrodes by a predetermined amount. Specifically, the electrodes to which each two neighboring gold wires are connected are spaced from each other such, that the space between each two neighboring gold wires is substantially equal to their diameter when they have streamed.

Specifically, the distance between each two neighboring electrodes is calculated in accordance with Equation 5 below, which is obtained as a result of transforming Equation 2.

d′=d+(L/100)(x₁−x₂) [Equation 5]

In Equation 5, d′ is the distance between two neighboring electrodes; d, the diameter of two neighboring gold wires 1 and 2 (connected to the electrodes); L, the length of the gold wires 1 and 2; x₁, the gold wire streaming factor of the gold wire 1; and x₂, the gold wire streaming factor of the gold wire 2. In the example shown in FIG. 4, for example, the gold wire streaming factors of the gold wires 61 and 62 are substituted for x₁ and x₂, respectively.

Or alternatively, the distance between each two neighboring electrodes may be calculated in accordance with Equation 3, assuming that only one of each two neighboring gold wires streams in resin.

Assume, for example, that the gold wire streaming factors of the gold wires 61 and 66 are 2.0%, those of the gold wires 62 and 65 are 2.5%, and those of the gold wires 63 and 64 are 3.0%. It should be noted that in the above case, each gold wire streaming factor corresponds to the gold wire streaming factor X₃ in the example of FIG. 1A. Then, for example, assuming that s″ is equal to the diameter of the gold wires, each space s′ is obtained by substituting an appropriate value for the gold wire length L in Equation 9. Each space s′ corresponds to the distance between neighboring two of the electrodes 71, 72, 73, 74, 75, 76, and 77. It should be noted that the pitch at which the inner leads connected to these gold wires are disposed is set to a conventional fixed value.

The electrodes are arranged based on each distance d′ thus obtained. It should be noted that electrodes other than the above selected electrodes are spaced from one another in a conventional manner. Referring to FIG. 4, if d₁, denotes the distance between the electrodes 74 and 75, d₂ denotes both the distance between the electrodes 72 and 73 and the distance between electrodes 75 and 76, and d₃ denotes both the distance between the electrodes 71 and 72 and the distance between the electrodes 76 and 77, then the following relation holds: d₁>d₂ >d₃.

In FIG. 4, the gold wires 63 and 64, which have the largest gold wire streaming factor, are spaced at a larger distance than any other two neighboring gold wires adjacent to these gold wires since the electrodes 73 and 74 to which these gold wires are connected are spaced at a distance of approximately 400 μm. Further, the electrode 74 is positioned in the resin flow downstream of the electrode 73. (The resin flows in the direction indicated by arrow X.) Therefore, even if the gold wire 63 is displaced toward the gold wire 64 adjacent to it due to its streaming movement, the two gold wires 63 and 64 cannot possibly come into contact with each other and become shorted since they are designed to be spaced a large distance from each other. This means that no consideration need be given to the distance between the electrodes 73 and 74, allowing these electrodes to be set at conventional positions.

It should be noted that even though the present embodiment was described as applied to the above portion in which two electrodes are spaced at a distance of 400 μm, the present invention is not limited to this particular arrangement. The present invention can be applied to any portion in which gold wires stream a large distance since the distance between electrodes is large.

The present embodiment selects the 3 gold wires on each side of a portion in which two neighboring electrodes are spaced at a larger distance than any other two neighboring electrodes adjacent to these electrodes and changes only the distances between the electrodes to which the above selected gold wires are connected, making it possible to prevent gold wires from coming into contact with one another due to their streaming movement and thereby prevent occurrence of a short circuit even in a semiconductor package of substantially conventional size.

Third Embodiment

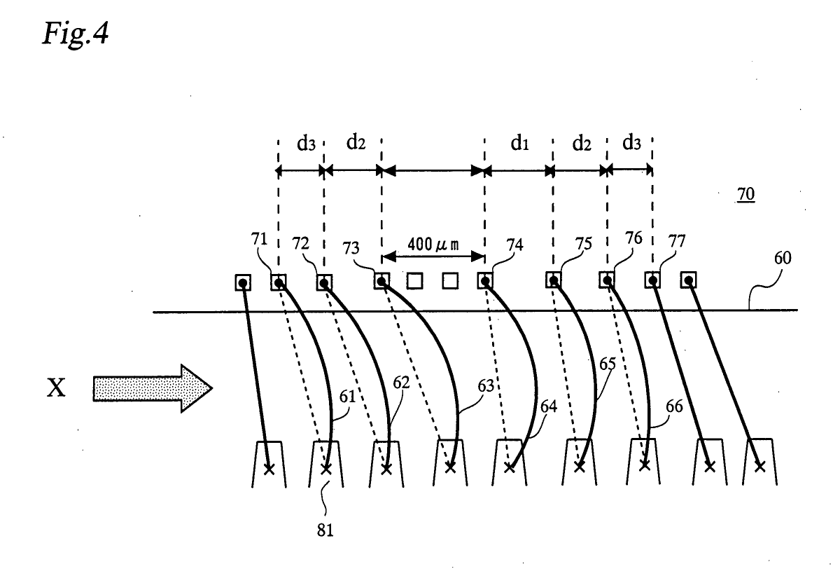

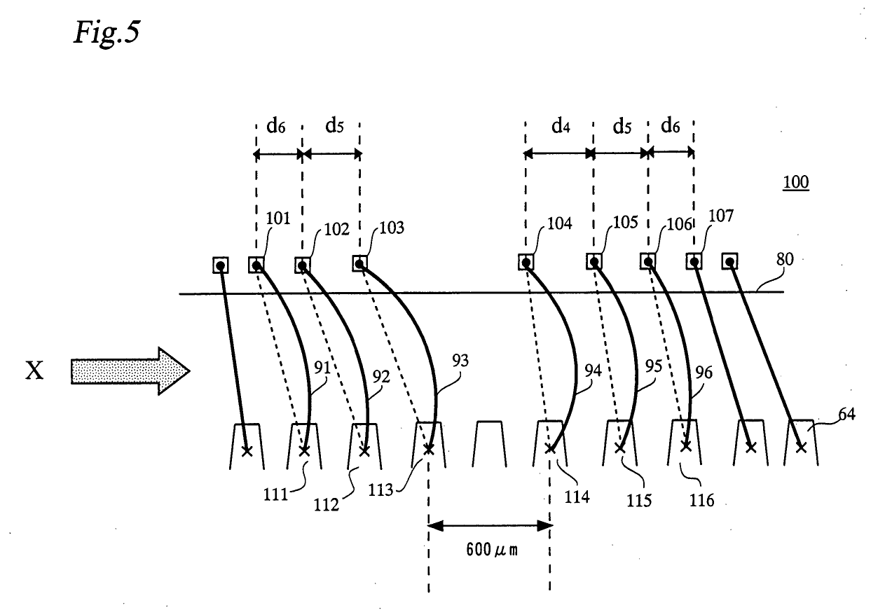

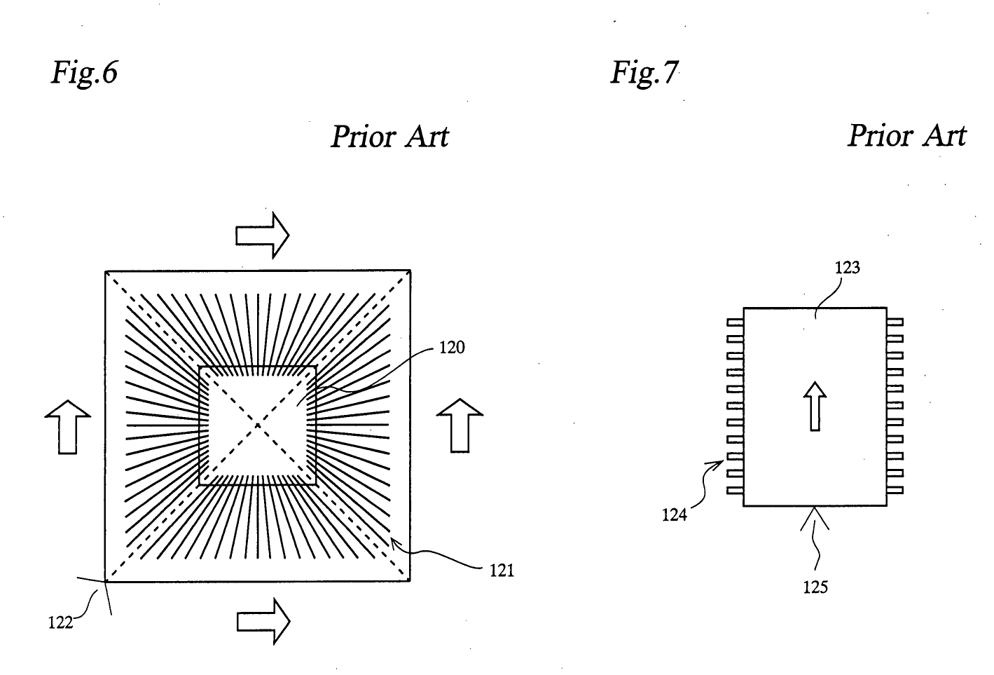

FIG. 5 is an enlarged plan view of a portion of a semiconductor device according to a third embodiment of the present invention. Referring to the figure, reference numeral 80 denotes the circumference of the semiconductor chip. The semiconductor chip is mounted on a mounting portion (not shown), and the chip, the mounting portion, one end of each external electrode terminal (described later), and the connection wires (described later) are sealed with a sealing member (not shown).

For example, a gold wire 91 is connected between an electrode 101 and one end of an inner lead 111. It should be noted that the inner lead 111 is a portion of an external electrode terminal and is disposed within the sealing member such that it faces the semiconductor chip 100. Further, the other end of the inner lead 111 extends from an outer lead (not shown) connected to an external component or device. The other gold wires 92 to 96 are also connected between their respective electrodes and their respective inner leads in the same manner.

Every semiconductor device has portions in which two neighboring inner leads (to which two neighboring gold wires are respectively connected) are spaced at a larger distance than any other two neighboring inner leads adjacent to these inner leads in order to suit design needs. If the distance between such neighboring inner leads (that is, the distance between the corresponding outer electrode terminals) is larger than a certain value, the flow of the resin injected to seal the semiconductor device changes at these portions, increasing the distance the gold wires stream.

In FIG. 5, the resin flowing in the direction indicated by arrow X causes every gold wire to stream. It should be noted that the an inner lead 113 to which a gold wire 93 is connected is spaced a distance of approximately 600 μm from an inner lead 114 to which a gold wire 94 is connected. At such a portion, the flow of the resin changes, increasing the distance the gold wires stream, which makes a short circuit between gold wires likely to occur. To solve this problem, the present embodiment performs the steps of: selecting the inner leads 113 and 114, and further selecting inner leads 111 and 112 on the left side of the inner lead 113 as well as inner leads 115 and 116 on the right side of the inner lead 114 (that is, selecting a total of 6 inner leads); determining the distance between each of the electrodes 101, 102, 103, 104, 105, and 106 (which are connected to the selected inner leads 111, 112, 113, 114, 115, and 116 by gold wires 91, 92, 93, 94, 95, and 96, respectively) and the neighboring electrode thereof in the direction (the X direction) in which the gold wires are displaced when the semiconductor device is sealed with a resin; and arranging the electrodes based on each determined distance.

According to the present embodiment, the amount of displacement of a gold wire due to its streaming movement (that is, the distance the gold wire streams) increases with decreasing distance from the above portion in which two neighboring inner leads are spaced at a larger distance than any other two neighboring inner leads adjacent to these inner leads. Referring to FIG. 5, if it is assumed that the gold wire streaming factors of the gold wires 93 and 94 are a %, those of the gold wires 92 and 95 are b %, and those of the gold wires 91 and 96 are c %, then the following relation holds: a>b>c. It should be noted that each dotted line indicates the position of a gold wire before it steams. It should be further noted that in FIG. 5, in addition to the gold wires 91, 92, 93, 94, 95, and 96, other gold wires also actually stream, but their gold wire streaming factors are less than c %. (For simplicity, the figure assumes that these other gold wires do not stream.)

Even though every gold wire streams due to a resin flow, as described above, the present embodiment allows focusing on only the gold wires 91, 92, 93, 94, 95, and 96. That is, the electrodes to which each neighboring two of these gold wires are connected may be spaced at a larger distance than any other two neighboring electrodes by a predetermined amount. Specifically, the electrodes to which each two neighboring gold wires are connected are spaced from each other such that the space between each two neighboring gold wires is substantially equal to their diameter when they have streamed.

Specifically, the distance between each two neighboring electrodes is calculated in accordance with Equation 6 below, which is obtained as a result of transforming Equation 2.

d′=d+(L/100)(x₁−x₂) [Equation 6]

In Equation 6, d′ is the distance between two neighboring electrodes; d, the diameter of two neighboring gold wires 1 and 2 (connected to the electrodes); L, the length of the gold wires 1 and 2; x₁, the gold wire streaming factor of the gold wire 1; and x₂, the gold wire streaming factor of the gold wire 2. In the example shown in FIG. 5, for example, the gold wire streaming factors of the gold wires 91 and 92 are substituted for x₁ and x₂, respectively.

Or alternatively, the distance between each two neighboring electrodes may be calculated in accordance with Equation 3, assuming that only one of each two neighboring gold wires streams in resin.

Assume, for example, that the gold wire streaming factors of the gold wires 91 and 96 are 2.0%, those of the gold wires 92 and 95 are 2.5%, and those of the gold wires 93 and 94 are 3.0%. It should be noted that in the above case, each gold wire streaming factor corresponds to the gold wire streaming factor X₃ in the example of FIG. 1. Then, for example, assuming that s″ is equal to the diameter of the gold wires, each space s′ is obtained by substituting an appropriate value for the gold wire length L in Equation 9. Each space s′ corresponds to the distance between neighboring two of the electrodes 101, 102, 103, 104, 105, 106, and 107. It should be noted that the pitch at which the inner leads connected to these gold wires are disposed is set to a conventional fixed value.

The electrodes are arranged based on each distance d′ thus obtained. It should be noted that electrodes other than the above selected electrodes are spaced from one another in a conventional manner. Referring to FIG. 5, if d₄ denotes the distance between the electrodes 104 and 105, d₅ denotes both the distance between the electrodes 102 and 103 and the distance between the electrodes 105 and 106, and d₆ denotes both the distance between the electrodes 101 and 102 and the distance between the electrodes 106 and 107, then the following relation holds: d₄>d₅>d₆.

In FIG. 5, the gold wires 93 and 94, which have the largest gold wire streaming factor, are spaced at a larger distance than any other two neighboring gold wires adjacent to these gold wires since the inner leads 113 and 114 to which these gold wires are connected are spaced at a distance of approximately 600 μm. Further, the inner lead 114 is positioned in the resin flow downstream of the inner lead 113. (The resin flows in the direction indicated by arrow X.) Therefore, even if the gold wire 93 is displaced toward the gold wire 94 adjacent to it due to its streaming movement, the two gold wires 93 and 94 cannot possibly come into contact with each other since they are designed to be spaced a large distance from each other. This means that no consideration need be given to the space between the electrodes 103 and 104, allowing these electrodes to be set at conventional positions.

It should be noted that even though the present embodiment was described as applied to the above portion in which two inner leads are spaced at a distance of 600 μm, the present invention is not limited to this particular arrangement. The present invention can be applied to any portion in which gold wires stream a large distance since the distance between inner leads is large.

The present embodiment selects the 3 gold wires on each side of a portion in which two neighboring inner leads are spaced at a larger distance than any other two neighboring inner leads adjacent to these inner leads and changes only the distances between the electrodes to which the above selected gold wires are connected, making it possible to prevent gold wires from coming into contact with one another due to their streaming movement and thereby prevent occurrence of a short circuit even in a semiconductor package of substantially conventional size.

It should be noted that the above first to third embodiments are not limited to any particular type of electrode arrangement. For example, the present invention can be applied to electrode arrangements such as center arrangements, staggered arrangements, straight arrangements, and random arrangements.

Further, even though the first to third embodiments were described as applied to gold wires, the present invention is not limited to any particular type of wire. Connection wires made of a material other than gold may be used.

The features and advantages of the present invention may be summarized as follows.

According to one aspect, the electrodes in a portion in which gold wires stream a large distance are spaced at larger intervals than other electrodes adjacent to them by a predetermined amount, making it possible to prevent gold wires from coming into contact with one another and thereby prevent occurrence of a shirt circuit even when the gold wires are displaced due to their streaming movement.

Further according to another aspect, the space between each two neighboring gold wires when they have streamed is set substantially equal to the diameter of these gold wires, making it possible to set the spaces between gold wires to within the measurement limit of inspection equipment as well as measuring these distances in a short time.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2003-180062, filed on Jun. 24, 2003 including specification, claims, drawings and summary, on which the Convention priority of the present application is based, are incorporated herein by reference in its entirety.

What is claimed is:

1. A semiconductor device comprising:
a semiconductor chip including a plurality of electrodes;
a mounting portion on which said semiconductor chip is mounted;
a plurality of external electrode terminals, one end of each external electrode terminal being disposed so as to face said semiconductor chip, the other end of each external electrode terminal being connected to an external component or device;
a plurality of connection wires each for connecting between one of said plurality of electrodes and one end of one of said plurality of external electrode terminals; and
a sealing member for resin-sealing said semiconductor chip, said mounting portion, said one end of said each external electrode terminal, and said plurality of connection wires, said sealing member having a rectangular shape;
wherein at least one of a corner portion of said semiconductor chip, a corner portion of said sealing member, and a portion in which two neighboring connection wires are spaced at a larger distance than any other two neighboring connection wires adjacent to said two neighboring connection wires is configured such that:
an electrode and another electrode adjacent to it are arranged such that the space between a connection wire connected to said electrode and another connection wire connected to said another electrode is substantially equal to the diameter of said connection wires when said connection wire connected to said electrode has been displaced toward said another connection wire connected to said another electrode due to a flow of a resin at a time of said resin-sealing, said connection wire and said another connection wire being adjacent to each other.

2. The semiconductor device according to claim 1, wherein said portion in which said two neighboring connection wires are spaced at a larger distance than said any other two neighboring connection wires adjacent to said two neighboring connection wires is further configured such that electrodes to which said two neighboring connection wires are respectively connected are spaced at a larger distance than any other two neighboring electrodes adjacent to said electrodes.

3. The semiconductor device according to claim 2, wherein the distance between said electrodes to which said two neighboring connection wires are respectively connected is 400 μm or more.

4. The semiconductor device according to claim 1, wherein said portion in which said two neighboring connection wires are spaced at a larger interval than said any other two neighboring connection wires adjacent to said two neighboring connection wires is further configured such that external electrode terminals to which said two neighboring connection wires are respectively connected are spaced at a larger distance than any other two neighboring external electrode terminals adjacent to said external electrode terminals.

5. The semiconductor device according to claim 4, wherein the distance between said external electrode terminals to which said two neighboring connection wires are respectively connected is 600 μm or more.

6. The semiconductor device according to claim 1, wherein said corner portion of said semiconductor chip is further configured such that said electrode is one of six electrodes, three on each side of a diagonal line of said semiconductor chip.

7. The semiconductor device according to claim 1, wherein said corner portion of said sealing member is further configured such that said electrode is one of six electrodes respectively connected through connection wires to six external electrode terminals, three on each side of a diagonal line of said sealing member.

8. The semiconductor device according to claim 1, wherein said portion in which said two neighboring connection wires are spaced at a larger distance than said any other two neighboring connection wires adjacent to said two neighboring connection wires is further configured such that said electrode is one of six electrodes to which said two neighboring connection wires and other four connection wires are respectively connected, two of said other four connection wires being on one side of said two neighboring connection wires, the other two of said other four connection wires being on the other side of said two neighboring connection wires.

9. The semiconductor device according to claim 8, wherein said portion in which said two neighboring connection wires are spaced at a larger distance than said any other two neighboring connection wires adjacent to said two neighboring connection wires is further configured such that electrodes to which said two neighboring connection wires are respectively connected are spaced at a larger distance than any other two neighboring electrodes adjacent to said electrodes.

10. The semiconductor device according to claim 9, wherein the distance between said electrodes to which said two neighboring connection wires are respectively connected is 400 μm or more.

11. The semiconductor device according to claim 8, wherein said portion in which said two neighboring connection wires are spaced at a larger interval than said any other two neighboring connection wires adjacent to said two neighboring connection wires is further configured such that external electrode terminals to which said two neighboring connection wires are respectively connected are spaced at a larger distance than any other two neighboring external electrode terminals adjacent to said external electrode terminals.

12. The semiconductor device according to claim 11, wherein the distance between said external electrode terminals to which said two neighboring connection wires are respectively connected is 600 μm or more.

13. The semiconductor device according to claim 1, wherein said plurality of external electrode terminals each include an outer lead and an inner lead, said outer lead being connected to an external component or device, said inner lead being disposed within said sealing member so as to face said semiconductor chip.

14. The semiconductor device according to claim 1, wherein said plurality of connection wires are gold wires.
